(19) United States
(12) Patent Application Publication
(10) Pub. No.: US 2016/0288018 A1
(43) Pub. Date: Oct. 6, 2016

(54) DEOXYGENATION APPARATUS AND SUBSTRATE PROCESSING APPARATUS

(71) Applicant: SCREEN Holdings Co., Ltd., Kyoto (JP)

(72) Inventors: Noriyuki KIKUMOTO, Kyoto (JP); Mitsutoshi SASAKI, Kyoto (JP); Kenji KOBAYASHI, Kyoto (JP)

(21) Appl. No.: 15/084,056

(22) Filed: Mar. 29, 2016

(30) Foreign Application Priority Data
Mar. 31, 2015 (JP) P2015-71336

(51) Int. Cl. B01D 19/00; H01L 21/67; B08B 3/08

(52) U.S. Cl. CPC B01D 19/0005; B01D 19/0063; B08B 3/08; H01L 21/67051

(57) ABSTRACT

A deoxygenation apparatus reduces the concentration of dissolved oxygen in a target liquid. The deoxygenation apparatus includes a reservoir for holding the target liquid, a gas supply part for supplying an additive gas different from oxygen into the target liquid in the reservoir, a storage part for storing correlation information indicating the relationship between the concentration of dissolved oxygen in the target liquid and a total supply amount that is a total amount of the additive gas supplied from the gas supply part into the target liquid from when supply was started, and a calculation part for obtaining the concentration of dissolved oxygen in the target liquid on the basis of the total supply amount and the correlation information. The concentration of dissolved oxygen in the target liquid is easily acquired without measuring the concentration of dissolved oxygen in the target liquid with an oxygen analyzer.

### TECHNICAL FIELD

The present invention relates to a deoxygenation apparatus for reducing the concentration of dissolved oxygen in a target liquid, and a substrate processing apparatus including the deoxygenation apparatus.

### BACKGROUND ART

In the process of manufacturing semiconductor substrates (hereinafter, simply referred to as “substrates”), various types of processing are conventionally performed on the substrates by supplying processing liquids to the substrates. One example is cleaning processing for supplying a cleaning liquid onto a substrate and washing away foreign substances adhering to the surface of the substrate. In the case where hydrofluoric acid is used as a cleaning liquid, foreign substances adhering to an oxide film on the surface of the substrate are removed by removing the oxide film.

Such liquid processing performed on substrates requires that processing liquids supplied to the substrates have low concentrations of dissolved oxygen in order to avoid oxidation of the surfaces of substrates. For example, vacuum degassing and bubbling are known as methods for reducing the concentration of dissolved oxygen in a processing liquid. A deaeration/aeration apparatus disclosed in Japanese Patent Application Laid-Open No. H7-328313 (Document 1) uses vacuum degassing. The deaeration/aeration apparatus produces a vacuum environment or a low-pressure environment in the external space surrounding deionized water to reduce the concentration of dissolved oxygen or other gases in the deionized water. A deoxidation apparatus disclosed in Japanese Patent Application Laid-Open No. 2005-7309 (Document 2) uses bubbling. In the deoxidation apparatus, a gas suction part is provided in a circulating pump on circulating piping that circulates treatment water in a water tank, and a nitrogen gas is supplied to the gas suction part. Thus, air bubbles of the nitrogen gas are supplied to the treatment water in the water tank, which reduces the concentration of dissolved oxygen in the treatment water.

Incidentally, the use of vacuum degassing for deaeration of a processing liquid increases not only the size of the apparatus for use in deaeration but also the manufacturing cost of the apparatus. Meanwhile, with the deoxygenation apparatus of Document 2, it is not possible to know whether the concentration of dissolved oxygen in the treatment water has dropped to a target concentration. It is conceivable to provide the deoxygenation apparatus with a dissolved oxygen analyzer, but a high-cost dissolved oxygen analyzer is necessary to accurately measure the concentration of dissolved oxygen, increasing the manufacturing cost of the apparatus.

### SUMMARY OF INVENTION

The present invention is directed to a deoxygenation apparatus for reducing the concentration of dissolved oxygen in a target liquid, and it is an object of the present invention to easily acquire the concentration of dissolved oxygen in the target liquid.

A deoxygenation apparatus according to the present invention includes a reservoir for holding a target liquid, a gas supply part for supplying an additive gas that is different from oxygen into the target liquid held in the reservoir, a storage part for storing correlation information that indicates a relationship between a total supply amount and the concentration of dissolved oxygen in the target liquid, the total supply amount being a total amount of the additive gas supplied from the gas supply part into the target liquid from when supply was started, and a calculation part for obtaining the concentration of dissolved oxygen in the target liquid on the basis of the total supply amount and the correlation information. The deoxygenation apparatus enables the concentration of dissolved oxygen in the target liquid to be easily acquired.

In a preferred embodiment of the present invention, the deoxygenation apparatus further includes a supply control part for controlling a unit supply amount that is an amount of the additive gas supplied from the gas supply part per unit of time. When the concentration of dissolved oxygen obtained by the calculation part has dropped to a predetermined target concentration or less, the supply control part reduces the unit supply amount to a concentration-maintaining supply amount that maintains the concentration of dissolved oxygen in the target liquid.

More preferably, the unit supply amount at the start of supply of the additive gas into the target liquid is a first supply amount, and the supply control part reduces the unit supply amount to a second supply amount that is less than the first supply amount and greater than the concentration-maintaining supply amount, before the concentration of dissolved oxygen obtained by the calculation part drops to the target concentration.

Yet more preferably, the gas supply part includes a plurality of gas supply ports through which the additive gas is emitted within the reservoir, and a supply-port adjusting part for increasing the number of the plurality of gas supply ports when the unit supply amount is switched from the first supply amount to the second supply amount.

In another preferred embodiment of the present invention, the gas supply part includes a gas supply port through which the additive gas is emitted within the reservoir, and a supply-port changing part for changing a size of the gas supply port. The supply-port changing part increases the size of the gas supply port, before the concentration of dissolved oxygen obtained by the calculation part drops to the target concentration.

More preferably, the gas supply port is an overlapping portion of openings of two plate members that are stacked one on top of the other, and the supply-port changing part changes an area of the overlapping portion by changing relative positions of the two plate members.

Another deoxygenation apparatus according to the present invention includes a reservoir for holding a target liquid, a gas supply part for supplying an additive gas that is different from oxygen into the target liquid held in the reservoir. The gas supply part includes a gas supply port through which the additive gas is emitted within the reservoir, and a supply-port changing part for changing a size of the gas supply port. The deoxygenation apparatus is capable of changing the diameter of air bubbles of the additive gas supplied from the gas supply port into the target liquid in the reservoir.

In a preferred embodiment of the present invention, the gas supply port is an overlapping portion of openings of two plate members that are stacked one on top of the other, and the supply-port changing part changes an area of the overlapping portion by changing relative positions of the two plate members.

The present invention is also directed to a substrate processing apparatus for processing a substrate. The substrate processing apparatus according to the present invention includes the deoxygenation apparatus described above, and a processing-liquid supply part for supplying a processing liquid to a substrate, the processing liquid including the target liquid having a concentration of dissolved oxygen that has been reduced by the deoxygenation apparatus.

These and other objects, features, aspects and advantages of the present invention will become more apparent from the following detailed description of the present invention when taken in conjunction with the accompanying drawings.

### BRIEF DESCRIPTION OF DRAWINGS

FIG. 1 illustrates a configuration of a substrate processing apparatus according to a first embodiment;

FIG. 2 illustrates a configuration of a deoxygenation apparatus;

FIG. 3 is a plan view of the deoxygenation apparatus;

FIG. 4 illustrates a relationship between a total supply amount of an additive gas and the concentration of dissolved oxygen in a target liquid;

FIG. 5 illustrates a configuration of a deoxygenation apparatus according to a second embodiment;

FIG. 6 illustrates a configuration of a deoxygenation apparatus according to a third embodiment;

FIG. 7 illustrates a configuration of a deoxygenation apparatus according to a fourth embodiment; and

FIG. 8 is a perspective view illustrating part of an emitting part and a supply-port changing part.

### DESCRIPTION OF EMBODIMENTS

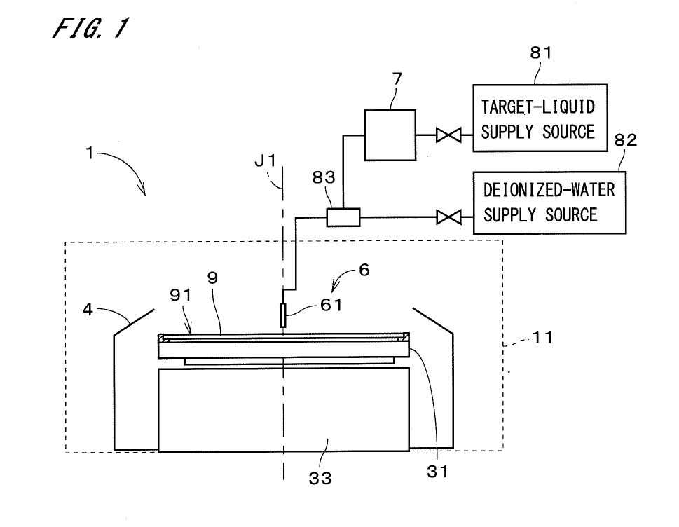

FIG. 1 illustrates a configuration of a substrate processing apparatus 1 that includes a deoxygenation apparatus 7 according to a first embodiment of the present invention. The substrate processing apparatus 1 is a sheet-fed apparatus for processing semiconductor substrates 9 (hereinafter, simply referred to as “substrates 9”) one at a time. The substrate processing apparatus 1 performs liquid processing (e.g., cleaning processing) by supplying a processing liquid to a substrate 9. FIG. 1 illustrates part of the configuration of the substrate processing apparatus 1 in a cross section. The processing liquid may, for example, be dilute hydrofluoric acid that is diluted with deionized water.

The substrate processing apparatus 1 includes a housing 11, a substrate holder 31, a substrate rotation mechanism 33, a cup part 4, a processing-liquid supply part 6, and the deoxygenation apparatus 7. The housing 11 houses, for example, the substrate holder 31 and the cup part 4. In FIG. 1, the housing 11 is indicated by a broken line.

The substrate holder 31 is a generally disk-shaped member centered on a central axis J1 pointing in the up-down direction. The substrate 9 is placed above the substrate holder 3, with an upper surface 91 thereof facing upward. The upper surface 91 of the substrate 9 has, for example, been provided with a fine irregular pattern in advance. The substrate holder 31 holds the substrate 9 in a horizontal position. The substrate rotation mechanism 33 is located below the substrate holder 31. The substrate rotation mechanism 33 rotates the substrate 9 along with the substrate holder 31 about the central axis J1.

The cup part 4 is a ring-shaped member centered on the central axis J1 and is located radially outward of the substrate 9 and the substrate holder 31. The cup part 4 covers the entire circumference of the substrate 9 and the substrate holder 31 and receives, for example, a processing liquid that is dispersed from the substrate 9 to the surroundings. The cup part 4 has a discharge port (not shown) at the bottom. The processing liquid or other substance received by the cup part 4 is discharged through the discharge port to the outside of the cup part 4 and the housing 11.

The processing-liquid supply part 6 includes an upper nozzle 61. The upper nozzle 61 is located above the central part of the substrate 9. The tip of the upper nozzle 61 has ejection ports through which processing liquid is ejected. The processing liquid ejected from the upper nozzle 61 is supplied to the upper surface 91 of the substrate 9. The upper nozzle 61 is connected via, for example, piping and valves to a mixing part 83, the deoxygenation apparatus 7, a target-liquid supply source 81, and a deionized-water supply source 82.

In the substrate processing apparatus 1, hydrofluoric acid, which is the liquid targeted for deoxygenation processing (hereinafter, referred to as a “target liquid”), is supplied from the target-liquid supply source 81 to the deoxygenation apparatus 7. In the deoxygenation apparatus 7, processing for deoxygenating the hydrofluoric acid is performed to reduce the concentration of dissolved oxygen in the hydrofluoric acid to a concentration that is lower than an upper limit value for the concentration of dissolved oxygen required for the processing liquid in processing the substrate 9. The deoxygenated hydrofluoric acid is sent from the deoxygenation apparatus 7 to the mixing part 83. The mixing part 83 combines the hydrofluoric acid received from the deoxygenation apparatus 7 with the deionized water received from the deionized-water supply source 82 to generate dilute hydrofluoric acid, which is a processing liquid. The processing liquid includes the target liquid having a concentration of dissolved oxygen that has been reduced by the deoxygenation apparatus 7. The mixing part 83 may, for example, be a mixing valve. The deionized water sent to the mixing part 83 has undergone deoxygenation processing in advance, and the concentration of dissolved oxygen in the deionized water is lower than the upper limit value for the concentration of dissolved oxygen required for the processing liquid in processing the substrate 9.

The processing liquid is sent from the mixing part 83 to the upper nozzle 61 and ejected from the upper nozzle 61 toward the central part of the upper surface 91 of the substrate 9. The processing liquid supplied onto the upper surface 91 of the substrate 9 is moved radially outward on the upper surface 91 by a centrifugal force and dispersed off the outer edge of the substrate 9 toward the cup part 4. The processing liquid received by the cup part 4 is discharged through the above discharge port to the outside of the cup part 4 and the housing 11. In the substrate processing apparatus 1, the processing liquid is supplied to the upper surface 91 of the substrate 9 for a predetermined period of time to perform liquid processing on the upper surface 91 of the substrate 9. After the predetermined period of time has elapsed, the supply of the processing liquid to the substrate 9 is stopped, and the liquid processing performed on the substrate 9 ends.

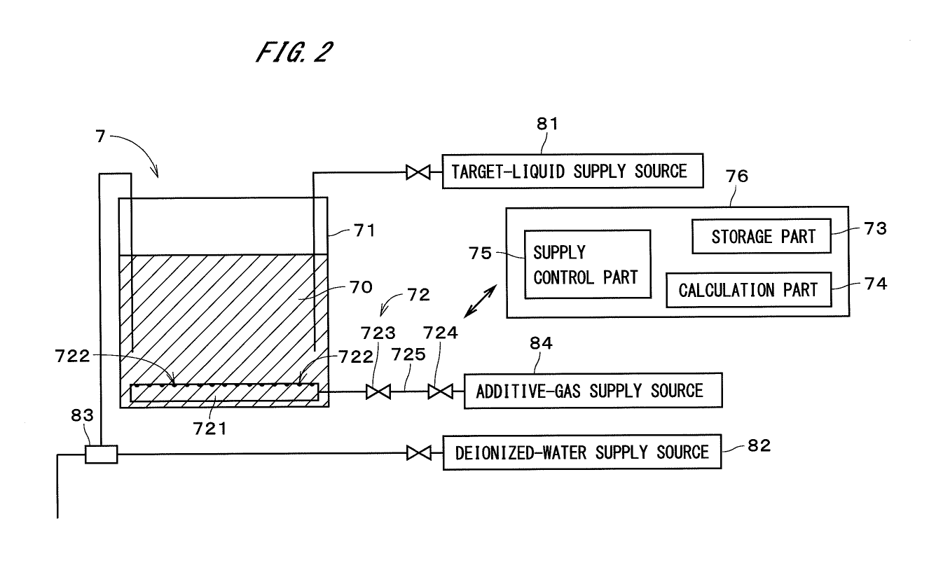

FIG. 2 illustrates a configuration of the deoxygenation apparatus 7. FIG. 2 also illustrates configurations of constituent elements other than the deoxygenation apparatus 7. The deoxygenation apparatus 7 is an apparatus for reducing the concentration of dissolved oxygen in the target liquid. The deoxygenation apparatus 7 includes a reservoir 71, a gas supply part 72, and a computer 76. FIG. 2 illustrates the interior of the reservoir 71. The reservoir 71 holds hydrofluoric acid that is the target liquid supplied from the target-liquid supply source 81. The reservoir 71 may, for example, be a container having a generally rectangular parallelepiped shape. The space in the reservoir 71 is an enclosed space. The reservoir 71 has an exhaust valve (not shown) in the upper part to maintain the space within the reservoir 71 at a predetermined pressure.

The gas supply part 72 includes a gas emitting part 721 provided with multiple gas supply ports 722, a supply-port adjusting part 723, and a flow-rate adjusting part 724. The gas emitting part 721 is located in the vicinity of the bottom of the reservoir 71. The gas emitting part 721 is connected via piping 725 to an additive-gas supply source 84. The supply-port adjusting part 723 and the flow-rate adjusting part 724 are provided on the piping 725. An additive gas supplied from the additive-gas supply source 84 to the gas emitting part 721 is supplied through the gas supply ports 722 into the target liquid 70 in the reservoir 71. The additive gas is a gas of a different type from oxygen, which is a target gas whose dissolved concentration in the target liquid 70 is to be reduced. Preferably, an inert gas may be used as the additive gas. The deoxygenation apparatus 7 illustrated in FIG. 2 uses a nitrogen (N2) gas as the additive gas. The processing for deoxygenating the target liquid 70 is performed by supplying the additive gas from the gas emitting part 721 into the target liquid 70, and accordingly, the concentration of dissolved oxygen in the target liquid 70 is reduced.

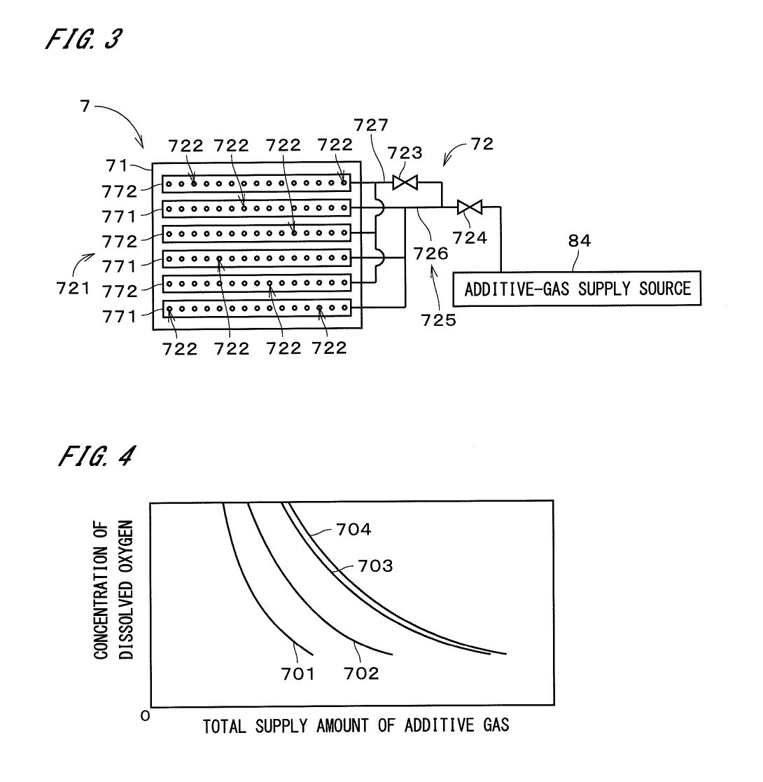

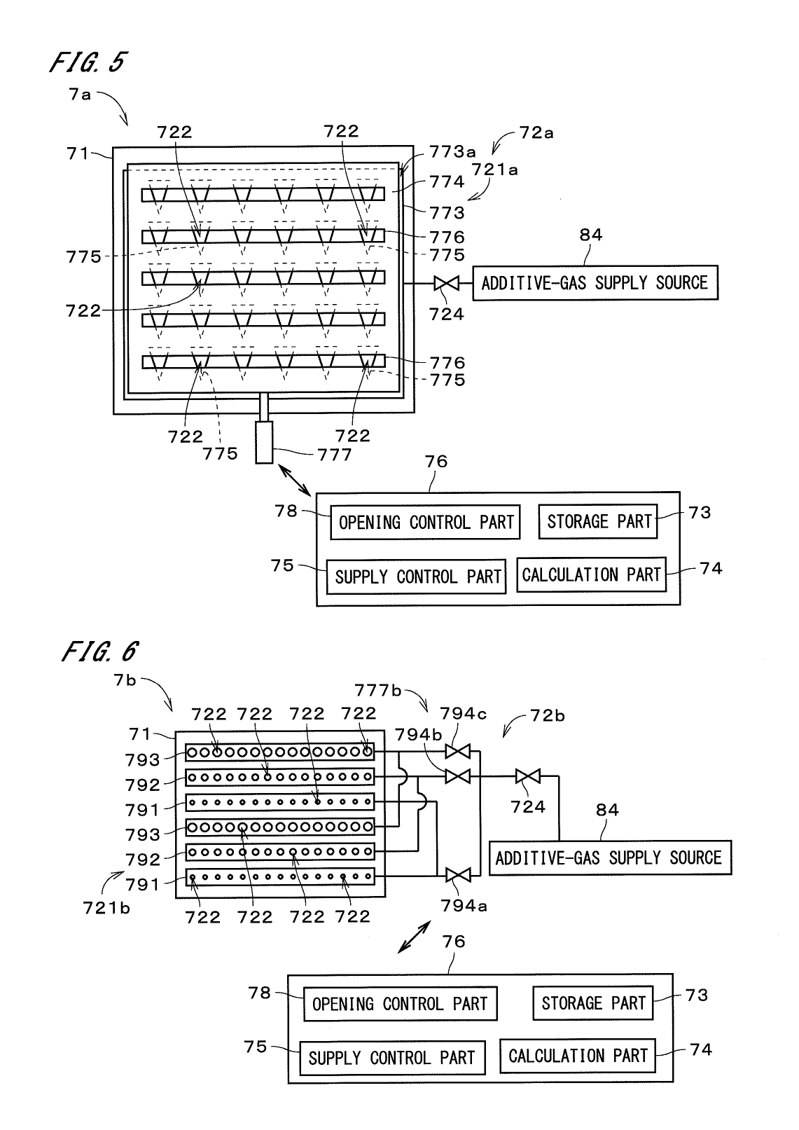

FIG. 3 is a plan view of the deoxygenation apparatus 7. FIG. 3 illustrates the interior of the reservoir 71 (the same applies to FIGS. 5 to 7). The computer 76 is not shown in FIG. 3. The gas emitting part 721 includes a first emitting part 771 and a second emitting part 772. In the example illustrated in FIG. 3, three first emitting parts 771 and three second emitting parts 772 are alternately arranged. The number of first emitting parts 771 and the number of second emitting parts 772 may be one or more. The first emitting parts 771 and the second emitting parts 772 are generally straight conduit lines. The first emitting parts 771 and the second emitting parts 772 are each provided with multiple gas supply ports 722 through which the additive gas is emitted within the reservoir 71. The first emitting parts 771 and the second emitting parts 772 each have multiple gas supply ports 722 of the same shape and size arranged at approximately equal intervals. In the deoxygenation apparatus 7, air bubbles of the additive gas are supplied from each gas supply port 722 into the target liquid 70 (see FIG. 2).

The piping 725 includes first piping 726 that is connected to the first emitting parts 771, and second piping 727 that branches off from the first piping 726 and is connected to the second emitting parts 772. The flow-rate adjusting part 724 is located upstream of the branch point between the first piping 726 and the second piping 727 (i.e., at a position close to the additive-gas supply source 84), and adjusts the amount of the additive gas supplied to the gas emitting part 721. The supply-port adjusting part 723 is located on the second piping 727. The supply-port adjusting part 723 switches between supplying the additive gas to the second emitting part 772 and stopping the supply.

When, in the gas supply part 72, the supply-port adjusting part 723 stops the supply of the additive gas to the second emitting parts 772, the additive gas from the additive-gas supply source 84 is supplied through the gas supply ports 722 of the first emitting parts 771 into the target liquid 70. When the additive gas is supplied to the second emitting parts 772 by the supply-port adjusting part 723, the additive gas from the additive-gas supply source 84 is supplied through the gas supply ports 722 of the first emitting parts 771 and the second emitting parts 772 into the target liquid 70. That is, the supply-port adjusting part 723 is a supply-port-number changing part that changes the number of the gas supply ports 722 through which the gas is supplied into the target liquid 70.

The computer 76 illustrated in FIG. 2 is configured as a general computer system that includes, for example, a CPU that performs various types of arithmetic processing, a ROM that stores basic programs, and a RAM that stores various types of information. The computer 76 implements the functions of a storage part 73, a calculation part 74, and a supply control part 75. In other words, the computer 76 includes the storage part 73, the calculation part 74, and the supply control part 75.

The storage part 73 stores correlation information that indicates the relationship between a total supply amount of the additive gas and the concentration of dissolved oxygen in the target liquid 70. The total supply amount of the additive gas refers to a total amount of the additive gas supplied from the gas supply part 72 into the target liquid 70 in the reservoir 71 from when the supply was started. The correlation information is obtained by acquiring the above relationship illustrated in FIG. 4 through measurement and stored in advance in the storage part 73, before the substrate processing apparatus 1 performs processing on the substrate 9.

In FIG. 4, the horizontal axis indicates the total supply amount of the additive gas, and the vertical axis indicates the concentration of dissolved oxygen in the target liquid 70. Solid lines 701 to 704 in FIG. 4 indicate the relationships between the total supply amount of the additive gas and the concentration of dissolved oxygen in the target liquid 70. The difference among the solid lines 701 to 704 is the average diameter of air bubbles of the additive gas supplied into the target liquid 70 (i.e., average value of the diameters of air bubbles). The solid line 701 indicates air bubbles with the smallest average diameter, the solid line 702 indicates air bubbles with the second smallest average diameter, the solid line 703 indicates air bubbles with the third smallest average diameter, and the solid line 704 indicates air bubbles with the largest average diameter. The amount of the additive gas supplied from the gas supply part 72 into the target liquid 70 per unit of time (hereinafter, referred to as a “unit supply amount”) is the same among the solid lines 701 to 704.

As illustrated in FIG. 4, the concentration of dissolved oxygen decreases as the total supply amount of the additive gas increases. Also, the rate of decrease in the concentration of dissolved oxygen (i.e., degassing rate) increases as the average diameter of air bubbles of the additive gas decreases. The correlation information may virtually indicate the relationship between the total supply amount of the additive gas and the concentration of dissolved oxygen in the target liquid 70. For example, when the unit supply amount is constant, the correlation information may be information indicating the relationship between a total supply time of the additive gas (i.e., time elapsed since the start of the supply) and the concentration of dissolved oxygen.

The supply control part 75 illustrated in FIG. 2 controls the flow-rate adjusting part 724 to control the unit supply amount of the additive gas supplied from the gas supply part 72. The calculation part 74 obtains the concentration of dissolved oxygen in the target liquid 70 on the basis of the total supply amount of the additive gas supplied into the target liquid 70 and the above correlation information stored in the storage part 73. The total supply amount of the additive gas may, for example, be acquired on the basis of control records that show control of the flow-rate adjusting part 724 by the supply control part 75.

In this way, in the deoxygenation apparatus 7, the storage part 73 stores correlation information that indicates the relationship between the total supply amount of the additive gas supplied into the target liquid 70 and the concentration of dissolved oxygen in the target liquid 70, and the calculation part 74 obtains the concentration of dissolved oxygen in the target liquid 70 on the basis of the total supply amount of the additive gas supplied from the gas supply part 72 and the correlation information. Thus, the concentration of dissolved oxygen in the target liquid 70 is easily acquired without having to measure the concentration of dissolved oxygen in the target liquid 70 with, for example, an oxygen analyzer. Consequently, the manufacturing cost of the deoxygenation apparatus 7 is reduced.

In the deoxygenation apparatus 7, when the concentration of dissolved oxygen in the target liquid 70 obtained by the calculation part 74 drops to a predetermined target concentration or less, the supply control part 75 controls the flow-rate adjusting part 724 to reduce the unit supply amount of the additive gas to a concentration-maintaining supply amount. The concentration-maintaining supply amount is a flow rate of the additive gas supplied into the target liquid 70 per unit of time in order to maintain the concentration of dissolved oxygen in the target liquid 70 that has dropped to the target concentration or less. The target concentration may, for example, be set to a concentration that is lower than the concentration of dissolved oxygen in the above deionized water supplied to the mixing part 83. The concentration-maintaining supply amount is lower than the unit supply amount of the additive gas supplied during deoxygenation processing. The concentration of dissolved oxygen in the target liquid 70 is thus maintained at the target concentration or less while reducing the amount of the additive gas used. The concentration-maintaining supply amount may, for example, be zero. That is, the additive gas needs not be supplied into the target liquid 70 having a concentration of dissolved oxygen that has reached the target concentration or less, if it is possible to maintain the concentration of dissolved oxygen in the target liquid 70 at the target concentration or less.

In the deoxygenation apparatus 7, the supply control part 75 controls the flow-rate adjusting part 724 to reduce the unit supply amount of the additive gas, before the concentration of dissolved oxygen in the target liquid 70 obtained by the calculation part 74 drops to the target concentration. More specifically, the unit supply amount is reduced from a first supply amount to a second supply amount when the concentration of dissolved oxygen in the target liquid 70 has dropped to a threshold concentration, which is higher than the target concentration, where the first supply amount is a unit supply amount of the additive gas at the start of supply of the additive gas into the target liquid 70, and the second supply amount is less than the first supply amount and greater than the concentration-maintaining supply amount.

Reducing the unit supply amount of the additive gas from the first supply amount to the second supply amount reduces the rate of increase in the total supply amount of the additive gas supplied into the target liquid 70 and also reduces the rate of decrease in the concentration of dissolved oxygen. This reduces the occurrence of overshoot in controlling the concentration of dissolved oxygen in the target liquid 70 to the target concentration. Consequently, the concentration of dissolved oxygen in the target liquid 70 is easily controlled to the target concentration. The above threshold concentration may preferably be lower than an average value of the above target concentration and an initial concentration, which is the concentration of dissolved oxygen in the target liquid 70 when the supply of the additive gas into the target liquid 70 is started. This suppresses an increase in the time required for the processing for deoxygenating the target liquid 70.

In the deoxygenation apparatus 7, the supply-port adjusting part 723 increases the number of the gas supply ports 722 when the unit supply amount of the additive gas is switched from the first supply amount to the second supply amount. More specifically, in the state where the unit supply amount of the additive gas is the first supply amount, the supply-port adjusting part 723 stops the supply of the additive gas to the second emitting parts 772 illustrated in FIG. 3, and the additive gas is supplied into the target liquid 70 from only the gas supply ports 722 of the first emitting parts 771. In the state where the unit supply amount of the additive gas is the second supply amount, the supply-port adjusting part 723 also supplies the additive gas to the second emitting parts 772, and the additive gas is supplied into the target liquid 70 from the first emitting parts 771 and the second emitting parts 772.

In this way, the distribution density of the gas supply ports 722 arranged at the bottom of the reservoir 71 is reduced (i.e., the gas supply ports 722 are sparsely arranged) when the unit supply amount of the additive gas is the first supply amount, which is relatively large. This reduces the possibility that air bubbles of the additive gas supplied from the closely located gas supply ports 722 will join together and increase in diameter, consequently improving the efficiency of the processing for deoxygenating the target liquid 70. When the unit supply amount of the additive gas is the second supply amount, which is relatively small, there is a small possibility that air bubbles of the additive gas supplied from the closely located gas supply ports 722 will join together because the number of air bubbles of the additive gas supplied from each gas supply port 722 per unit of time is small. In view of this, the distribution density of the gas supply ports 722 arranged at the bottom of the reservoir 71 is increased (i.e., the gas supply ports 722 are densely arranged) to improve the uniformity of the distribution of air bubbles of the additive gas in the target liquid 70. This consequently improves the efficiency of the processing for deoxygenating the target liquid 70.

FIG. 5 is a plan view of a deoxygenation apparatus 7a according to a second embodiment. The deoxygenation apparatus 7a may, for example, be provided in the substrate processing apparatus 1, instead of the deoxygenation apparatus 7 illustrated in FIG. 1. The deoxygenation apparatus 7a illustrated in FIG. 5 has approximately the same configuration as the deoxygenation apparatus 7 illustrated in FIGS. 2 and 3, except that a gas supply part 72a is provided in place of the gas supply part 72 in FIGS. 2 and 3 and that the computer 76 further includes an opening control part 78. In the following description, constituent elements of the deoxygenation apparatus 7a that correspond to constituent elements of the deoxygenation apparatus 7 are given the same reference numerals.

The gas supply part 72a includes a gas emitting part 721a provided with multiple gas supply ports 722, and a flow-rate adjusting part 724. The gas emitting part 721a is connected via piping to the additive-gas supply source 84. The flow-rate adjusting part 724 is provided on the piping. The gas emitting part 721 a includes a box part 773 having a generally rectangular parallelepiped shape, a slit plate 774 that is a generally rectangular plate member, and a supply-port changing part 777. The box part 773 is a relatively thin hollow member located at the bottom of the reservoir 71. The box part 773 is connected to the additive-gas supply source 84. The slit plate 774 is stacked on a top surface portion 773a of the box part 773. The supply-port changing part 777 moves the slit plate 774 horizontally in a predetermined travel direction (up-down direction in FIG. 5). The opening control part 78 controls the supply-port changing part 777 on the basis of the output from the calculation part 74.

The top surface portion 773a of the box part 773 has multiple openings 775 that communicate with the internal space of the box part 773. In the example illustrated in FIG. 5, thirty openings 775 are arranged in a matrix form. Each opening 775 has a triangular shape in the example illustrated in FIG. 5. A width of each opening 775 in a width direction perpendicular to the above travel direction (hereinafter, simply referred to as the “width”) gradually increases from the lower side to the upper side in FIG. 5 (i.e., from one side to the other side in the above travel direction). The slit plate 774 has multiple openings 776. In the example illustrated in FIG. 5, five openings 776 are arranged in the above travel direction. The openings 776 in the example illustrated in FIG. 5 have a generally rectangular shape extending in the width direction, and overlap partially with six openings 775 that are arranged in the width direction.

In the gas supply part 72a, overlapping portions of the openings 775 in the box part 773 and the openings 776 in the slit plate 774 form the gas supply ports 722 through which the additive gas supplied from the additive-gas supply source 84 to the gas emitting part 721 a is emitted within the reservoir 71. The area of the overlapping portions of the openings 775 and 776, i.e., the size of the gas supply ports 722, is changed by the supply-port changing part 777 moving the slit plate 774 in the travel direction. More specifically, the size of the gas supply ports 722 decreases when the slit plate 774 is moved downward in FIG. 5, and the size of the gas supply ports 722 increases when the slit plate 774 is moved upward in FIG. 5.

When the top surface portion 773a of the box part 773 with the openings 775 is taken as a single plate member, the gas supply ports 722 are overlapping portions of the openings 775 and 776 of the two plate members (i.e., the top surface portion 773a of the box part 773 and the slit plate 774) that are stacked one on top of the other. The supply-port changing part 777 changes the area of the overlapping portions of the openings 775 and 776 by changing the relative positions of the two plate members. This configuration of the gas emitting part 721 a allows the size of the gas supply ports 722 to be easily changed. Thus, the diameter of air bubbles of the additive gas supplied from the gas supply ports 722 into the target liquid in the reservoir 71 is easily changed.

In the deoxygenation apparatus 7a, the calculation part 74 obtains the concentration of dissolved oxygen in the target liquid on the basis of the total supply amount of the additive gas supplied into the target liquid and the above correlation information (see FIG. 4) stored in the storage part 73, as in the deoxygenation apparatus 7 illustrated in FIGS. 2 and 3. Thus, as described above, the concentration of dissolved oxygen in the target liquid is easily acquired without having to measure the concentration of dissolved oxygen in the target liquid with, for example, an oxygen analyzer.

In the deoxygenation apparatus 7a, the opening control part 78 controls the supply-port changing part 777 to increase the size of each gas supply port 722 by moving the slit plate 774 to the upper side in FIG. 5, before the concentration of dissolved oxygen in the target liquid obtained by the calculation part 74 drops to the target concentration. More specifically, the size of each gas supply port 722 is increased when the concentration of dissolved oxygen in the target liquid has dropped to the above threshold concentration, which is higher than the target concentration. This increases the diameter of air bubbles of the additive gas supplied from the gas supply ports 722 into the target liquid in the reservoir 71.

As described above, the rate of decrease in the concentration of dissolved oxygen decreases as the average diameter of air bubbles of the additive gas increases (see FIG. 4). This reduces the occurrence of overshoot in controlling the concentration of dissolved oxygen in the target liquid to the target concentration. Consequently, the concentration of dissolved oxygen in the target liquid is easily controlled to the target concentration. The above threshold concentration may preferably be lower than the average value of the above target concentration and the initial concentration, which is the concentration of dissolved oxygen in the target liquid at the start of supply of the additive gas into the target liquid. This suppresses an increase in the time required for the processing for deoxygenating the target liquid.

FIG. 6 is a plan view of a deoxygenation apparatus 7b according to a third embodiment. The deoxygenation apparatus 7b may, for example, be provided in the substrate processing apparatus 1, instead of the deoxygenation apparatus 7 illustrated in FIG. 1. The deoxygenation apparatus 7b illustrated in FIG. 6 has approximately the same configuration as the deoxygenation apparatus 7a illustrated in FIG. 5, except that a gas supply part 72b is provided instead of the gas supply part 72a in FIG. 5. In the following description, constituent elements of the deoxygenation apparatus 7b that correspond to constituent elements of the deoxygenation apparatus 7a are given the same reference numerals.

The gas supply part 72b includes a gas emitting part 721b, a supply-port changing part 777b, and a flow-rate adjusting part 724. The gas emitting part 721b includes a first emitting part 791, a second emitting part 792, and a third emitting part 793. In the example illustrated in FIG. 6, two first emitting parts 791, two second emitting parts 792, and two third emitting parts 793 are sequentially arranged in the up-down direction in FIG. 6. The number of first emitting parts 791, the number of second emitting parts 792, and the number of third emitting parts 793 may be one or may be three or more. In the gas emitting part 721b, emitting parts of the same type are not adjacent to each other.

The first emitting parts 791, the second emitting parts 792, and the third emitting parts 793 are generally straight conduit lines. The first emitting parts 791, the second emitting parts 792, and the third emitting parts 793 are each provided with multiple gas supply ports 722 through which the additive gas is emitted within the reservoir 71. The gas supply ports 722 of the first emitting part 791, the gas supply ports 722 of the second emitting parts 792, and the gas supply ports 722 of the third emitting parts 793 have different sizes. In the example illustrated in FIG. 6, the first emitting parts 791 have the smallest gas supply ports 722, the second emitting parts 792 have the second smallest gas supply ports 722, and the third emitting parts 793 have the largest gas supply ports 722. In the deoxygenation apparatus 7b, air bubbles of the additive gas are supplied from each gas supply port 722 into the target liquid.

The supply-port changing part 777b includes three valves 794a, 794b, and 794c that are respectively provided on three types of piping that respectively connect the first emitting parts 791, the second emitting parts 792, and the third emitting parts 793 with the additive-gas supply source 84. The three valves 794a, 794b, and 794c are opened and closed by the supply-port changing part 777b such that the additive gas from the additive-gas supply source 84 is supplied into the target liquid through the gas supply ports 722 of one of the first emitting parts 791, the second emitting parts 792, and the third emitting parts 793. That is, the supply-port changing part 777b switches the emitting parts used to supply the additive gas from the additive-gas supply source 84 between the first emitting parts 791, the second emitting parts 792, and the third emitting parts 793 to change the size of the gas supply ports 722 to be used to supply the additive gas into the target liquid. Thus, the diameter of air bubbles of the additive gas supplied from the gas supply ports 722 into the target liquid in the reservoir 71 is easily changed.

In the deoxygenation apparatus 7b, the calculation part 74 obtains the concentration of dissolved oxygen in the target liquid on the basis of the total supply amount of the additive gas supplied into the target liquid and the above correlation information (see FIG. 4) stored in the storage part 73, as in the deoxygenation apparatus 7 illustrated in FIGS. 2 and 3. Thus, as described above, the concentration of dissolved oxygen in the target liquid is easily acquired without having to measure the concentration of dissolved oxygen in the target liquid with an oxygen analyzer, for example.

In the deoxygenation apparatus 7b, the opening control part 78 controls the supply-port changing part 777b to switch at least two valves among the valves 774a, 774b, and 774c to increase the size of the gas supply ports 722 through which the additive gas is emitted, before the concentration of dissolved oxygen in the target liquid obtained by the calculation part 74 drops to the target concentration. More specifically, a transmission destination of the additive gas from the additive-gas supply source 84 is switched, for example, from the first emitting parts 791 to the second emitting parts 792 when the concentration of dissolved oxygen in the target liquid has dropped to the above threshold concentration, which is higher than the target concentration. This increases the diameter of air bubbles of the additive gas supplied from the gas supply ports 722 into the target liquid in the reservoir 71.

As described above, the rate of decrease in the concentration of dissolved oxygen decreases as the average diameter of air bubbles of the additive gas increases (see FIG. 4). This reduces the occurrence of overshoot in controlling the concentration of dissolved oxygen in the target liquid to the target concentration. Consequently, the concentration of dissolved oxygen in the target liquid is easily controlled. The above threshold concentration may preferably be lower than the average value of the above target concentration and the initial concentration, which is the concentration of dissolved oxygen in the target liquid at the start of supply of the additive gas into the target liquid. This suppresses an increase in the time required for the processing for deoxygenating the target liquid.

While the gas emitting part 721b in the example illustrated in FIG. 6 includes the three types of emitting parts 791 to 793 that differ in the size of the gas supply ports 722, the number of types of the emitting parts is not limited to three. The gas emitting part 721b may include multiple types of emitting parts that differ in the size of the gas supply ports 722.

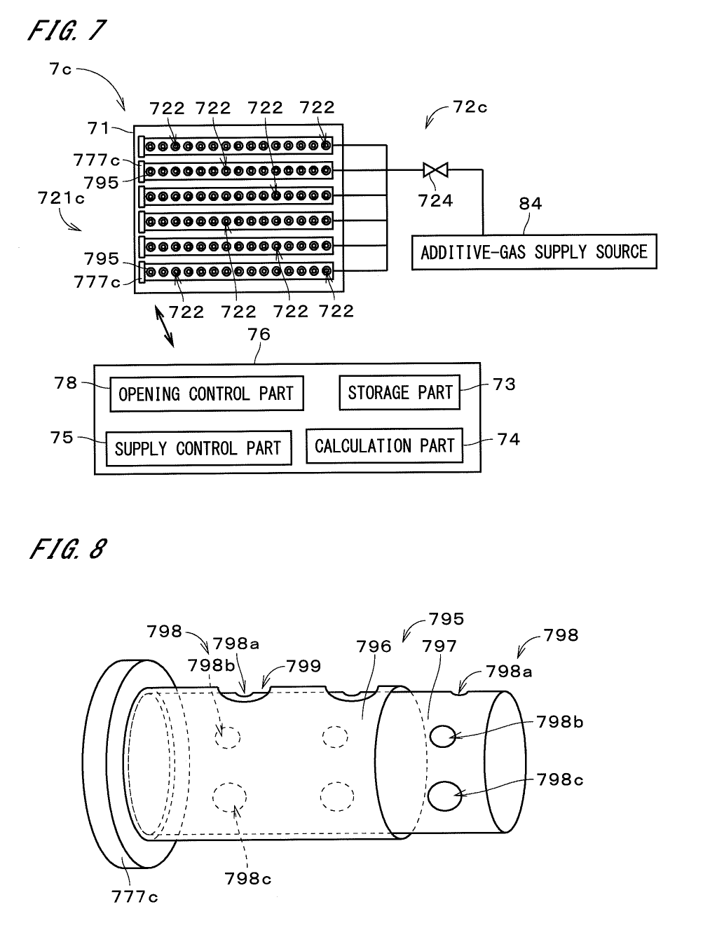

FIG. 7 is a plan view of a deoxygenation apparatus 7c according to a fourth embodiment. The deoxygenation apparatus 7c may, for example, be provided in the substrate processing apparatus 1, instead of the deoxygenation apparatus 7 illustrated in FIG. 1. The deoxygenation apparatus 7c illustrated in FIG. 7 has approximately the same configuration as the deoxygenation apparatus 7a illustrated in FIG. 5, except that a gas supply part 72c is provided instead of the gas supply part 72a in FIG. 5. In the following description, constituent elements of the deoxygenation apparatus 7c that correspond to constituent elements of the deoxygenation apparatus 7a are given the same reference numerals.

The gas supply part 72c includes a gas emitting part 721c, supply-port changing parts 777c, and a flow-rate adjusting part 724. The gas emitting part 721c includes multiple emitting parts 795 that are located at the bottom of the reservoir 71. Each emitting part 79 has multiple gas supply ports 722. In the example illustrated in FIG. 7, six emitting parts 795 are arranged in the up-down direction in FIG. 7. The number of emitting parts 795 may be one or more. A supply-port changing part 777c is connected to the left end of each emitting part 795 in FIG. 7.

FIG. 8 is an enlarged perspective view illustrating one supply-port changing part 777c and a portion in the vicinity of the left end of one emitting part 795. The other emitting parts 795 and the other supply-port changing parts 777c also have similar configurations to the configurations illustrated in FIG. 8. The emitting part 795 includes an outer cylinder part 796 and an inner cylinder part 797. The outer cylinder part 796 and the inner cylinder part 797 are cylindrical plate members. The inner cylinder part 797 is located inside the outer cylinder part 796 with a slight space therebetween. To facilitate comprehension of the drawing, part of the outer cylinder part 796 that covers the side surface of the inner cylinder part 797 is not shown in FIG. 8.

The side surface of the inner cylinder part 797 has multiple groups of openings 798 arranged in the longitudinal direction. Each group of openings 798 includes a small-sized opening 798a, a medium-sized opening 798b, and a large-sized opening 798c that are arranged in the circumferential direction of the inner cylinder part 797. The small-sized opening 798a is the smallest opening, the medium-sized opening 798b is the second smallest opening, and the large-sized opening 798c is the largest opening. In the example illustrated in FIG. 8, the small-sized opening 798a, the medium-sized opening 798b, and the large-sized opening 798c are generally circular through holes. Each group of openings 798 includes at least two different-sized openings.

The side surface of the outer cylinder part 796 has multiple outer openings 799 arranged in the longitudinal direction. The outer openings 799 are located at positions that correspond respectively to the groups of openings 798 in the longitudinal direction. The size of the outer openings 799 may be the same as or larger than the size of the large-sized opening 798c. In the example illustrated in FIG. 8, the outer openings 799 are generally circular through holes.

The inner cylinder part 797 is connected to the supply-port changing part 777c and rotated inside the outer cylinder part 796 by the supply-port changing part 777c. The outer cylinder part 796 does not rotate. As a result of the inner cylinder part 797 being rotated by the supply-port changing part 777c, one of the openings 798a to 798c in each group of openings 798 of the inner cylinder part 797 overlaps with an outer opening 799 of the outer cylinder part 796. In the gas supply part 72c, overlapping portions of the openings 798a to 798c of the inner cylinder part 797 and the outer openings 799 of the outer cylinder part 796 form the gas supply ports 722 through which the additive gas supplied from the additive-gas supply source 84 (see FIG. 7) to the gas emitting part 721c is emitted within the reservoir 71. The supply-port changing part 777c rotates the inner cylinder part 797 to change the area of the overlapping portions of the openings 798a to 798c and the outer openings 799, i.e., the size of the gas supply ports 722.

In the gas emitting part 721c of the deoxygenation apparatus 7c, the gas supply ports 722 are overlapping portions of the openings 799 and 798a to 798c of the two cylindrical plate members (i.e., outer cylinder part 796 and inner cylinder part 797) that are stacked one on top of the other. The supply-port changing part 777c changes the area of the overlapping portions of the openings 799 and 798a to 798c by changing the relative positions of the two cylindrical plate members in the circumferential direction. This configuration of the gas emitting part 721 c allows the size of the gas supply ports 722 to be easily changed. Thus, the diameter of air bubbles of the additive gas supplied from the gas supply ports 722 into the reservoir 71 is easily changed.

In the deoxygenation apparatus 7c illustrated in FIG. 7, the calculation part 74 obtains the concentration of dissolved oxygen in the target liquid on the basis of the total supply amount of the additive gas supplied into the target liquid and the above correlation information (see FIG. 4) stored in the storage part 73, as in the deoxygenation apparatus 7 illustrated in FIGS. 2 and 3. Thus, as described above, the concentration of dissolved oxygen in the target liquid is easily acquired without having to measure the concentration of dissolved oxygen in the target liquid with an oxygen analyzer, for example.

In the deoxygenation apparatus 7c, the opening control part 78 controls the supply-port changing part 777c to rotate the inner cylinder part 797 and increase the size of each gas supply port 722, before the concentration of dissolved oxygen in the target liquid obtained by the calculation part 74 drops to the target concentration. More specifically, the openings of the inner cylinder part 797 that overlap with the outer openings 799 of the outer cylinder part 796 are changed from, for example, the small-sized openings 798a to the medium-sized openings 798b when the concentration of dissolved oxygen in the target liquid has dropped to the above threshold concentration, which is higher than the target concentration. This increases the diameter of air bubbles of the additive gas supplied from the gas supply ports 722 into the target liquid in the reservoir 71.

As described above, the rate of decrease in the concentration of dissolved oxygen decreases (see FIG. 4) as the average diameter of air bubbles of the additive gas increases. This reduces the occurrence of overshoot in controlling the concentration of dissolved oxygen in the target liquid to the target concentration. Consequently, the concentration of dissolved oxygen in the target liquid is easily controlled to the target concentration. The above threshold concentration may preferably be lower than the average value of the above target concentration and the initial concentration, which is the concentration of dissolved oxygen in the target liquid at the start of supply of the additive gas into the target liquid. This suppresses an increase in the time required for the processing for deoxygenating the target liquid.

Although the inner cylinder part 797 in the example illustrated in FIG. 8 has the three types of openings 798a to 798c having different sizes, the size of the openings of the inner cylinder part 797 arranged in the circumferential direction are not limited to three types. In the gas supply part 72c, the side surface of the inner cylinder part 797 may have multiple types of openings of different sizes arranged in the circumferential direction. The gas supply part 72c may also be configured such that the supply-port changing part 777c rotates the outer cylinder part 796 without rotating the inner cylinder part 797. A configuration is also possible in which a cylindrical plate member that has one type of opening, like the outer cylinder part 796, is located inside a cylindrical member that has multiple types of openings, like the inner cylinder part 797.

The deoxygenation apparatus 7a illustrated in FIG. 5 is capable of performing deoxygenation processing on various types of target liquids. A change in the type of the target liquid and, accordingly, in the surface tension of the target liquid, changes the diameter of air bubbles of the additive gas even if the size of the gas supply ports 722 remains constant. More specifically, if the surface tension of the target liquid increases with the size of the gas supply ports 722 remaining constant, the diameter of air bubbles of the additive gas increases. As described above, the rate of decrease in the concentration of dissolved oxygen decreases as the diameter of air bubbles of the additive gas increases. Thus, it is preferable for the diameter of air bubbles of the additive gas supplied into the target liquid to be approximately constant, irrespective of the type of the target liquid, in order to always improve the efficiency of the deoxygenation processing even in the case where the type of the target liquid changes. If, depending on the type of the target liquid, there is a suitable rate of decrease in the concentration of dissolved oxygen for the deoxygenation processing, it is preferable for the diameter of air bubbles of the additive gas to be a diameter that is suitable for achieving the suitable rate of decrease.

The deoxygenation apparatus 7a includes, as described above, the reservoir 71 for holding the target liquid, and the gas supply part 72a for supplying the additive gas into the target liquid in the reservoir 71. The gas supply part 72a includes the gas supply ports 722 through which the additive gas is emitted within the reservoir 71, and the supply-port changing part 777 for changing the size of the gas supply ports 722. It is thus possible in the deoxygenation apparatus 7a to make the diameter of air bubbles of the additive gas supplied into the target liquid approximately constant, irrespective of the type of the target liquid. It is also possible to make the diameter of air bubbles of the additive gas supplied into the target liquid a suitable size for the type of target liquid. In this case, the storage part 73 and the calculation part 74 described above may be omitted from the deoxygenation apparatus 7a. The same applies to the deoxygenation apparatuses 7b and 7c illustrated in FIGS. 6 and 7.

Various modifications are possible with the deoxygenation apparatuses 7 and 7a to 7c and the substrate processing apparatus 1.

In the deoxygenation apparatus 7a illustrated in FIG. 5, for example, the supply control part 75 may control the flow-rate adjusting part 724 in parallel with the operation of increasing the size of the gas supply ports 722 to reduce the unit supply amount of the additive gas, before the concentration of dissolved oxygen in the target liquid obtained by the calculation part 74 drops to the target concentration. This further reduces the rate of decrease in the concentration of dissolved oxygen. Consequently, the occurrence of overshoot described above is reduced, and the concentration of dissolved oxygen in the target liquid is easily controlled to the target concentration. The same applies to the deoxygenation apparatuses 7b and 7c illustrated in FIGS. 6 and 7.

The deoxygenation apparatus 7 illustrated in FIGS. 2 and 3 does not necessarily have to reduce the unit supply amount of the additive gas before the concentration of dissolved oxygen in the target liquid drops to the target concentration. For example, if the concentration of dissolved oxygen in the target liquid is allowed to differ from the target concentration to some extent as long as the concentration of dissolved oxygen is less than or equal to the target concentration, the unit supply amount of the additive gas may be maintained constant until the concentration of dissolved oxygen drops to the target concentration or less.

The deoxygenation apparatus 7a illustrated in FIG. 5 does not necessarily have to increase the size of the gas supply ports 722 before the concentration of dissolved oxygen in the target liquid drops to the target concentration. For example, if the concentration of dissolved oxygen in the target liquid is allowed to differ from the target concentration to some extent as long as the concentration of dissolved oxygen is less than or equal to the target concentration, the size of the gas supply ports 722 may be maintained constant until the concentration of dissolved oxygen drops to the target concentration or less. Also, the deoxygenation apparatus 7a may include only a single gas supply port 722. The same applies to the deoxygenation apparatus 7b and 7c in FIGS. 6 and 7.

The deoxygenation apparatus 7 illustrated in FIGS. 2 and 3 may further include a large-sized tank that is connected via piping to the reservoir 71, and deoxygenation processing may be performed on all target liquids held in the large-size tank by circulating the target liquids in the large-sized tank and the target liquid that has undergone deoxygenation processing in the reservoir 71. The same applies to the deoxygenation apparatuses 7a to 7c in FIGS. 5 to 7.

In the deoxygenation apparatus 7 illustrated in FIGS. 2 and 3, the method by which the supply-port adjusting part 723 changes the number of gas supply ports 722 is not limited to switching between supplying the additive gas to the second emitting part 772 and stopping the supply, and various other methods are also applicable. For example, a configuration is possible in which, among the gas supply ports 722 distributed at approximately equal intervals across the entire bottom of the reservoir 71, some gas supply ports 22 are covered with a movable plate, the additive gas is supplied through uncovered gas supply ports 722, and the movable plate is retracted from above the gas supply ports 722 when increasing the number of gas supply ports 722.

In the substrate processing apparatus 1 illustrated in FIG. 1, the processing liquid is not limited to a mixture of the target liquid and deionized water as long as the target liquid included in the processing liquid has a concentration of dissolved oxygen that has been reduced by the deoxygenation apparatuses 7 and 7a to 7c. For example, the processing liquid may be a mixture of the target liquid and a liquid other than deionized water, or may be the target liquid itself.

In the substrate processing apparatus 1, two deoxygenation apparatuses 7 may be connected to the target-liquid supply source 81. Target liquid that has undergone deoxygenation processing in one of the deoxygenation apparatuses 7 (i.e., target liquid having a concentration of dissolved oxygen that has been reduced to the target concentration or less) may be used in the mixing part 83 to generate a processing liquid, and in parallel with this, the other deoxygenation apparatus 7 may perform deoxygenation processing on target liquid. In this case, when the concentration of dissolved oxygen obtained by the calculation part 74 has dropped to the target concentration or less in the other deoxygenation apparatus 7, the deoxygenation apparatus 7 that sends the target liquid to the mixing part 83 is switched from the one deoxygenation apparatus 7 to the other deoxygenation apparatus 7. In the one deoxygenation apparatus 7, the reservoir 71 is refilled with the target liquid from the target-liquid supply source 81, and deoxygenation processing is performed on the target liquid. Alternatively, the target-liquid supply source 81 may be connected to three or more deoxygenation apparatuses 7, and the target liquid may be supplied sequentially from these deoxygenation apparatuses 7 to the mixing part 83. The same applies to the case where the deoxygenation apparatuses 7a to 7c are provided in the substrate processing apparatus 1.

The substrate processing apparatus 1 may further include another deoxygenation apparatus 7 or one of the deoxygenation apparatuses 7a to 7c between the deionized-water supply source 82 and the mixing part 83, and this deoxygenation apparatus may perform deoxygenation processing on the deionized water supplied from the deionized-water supply source 82.

The substrate processing apparatus 1 may be used in liquid processing other than processing for cleaning semiconductor substrates. The substrate processing apparatus 1 may also be used to process substrates other than semiconductor substrates, such as glass substrates used in display devices including liquid crystal displays, plasma displays, and field emission displays (FED). The substrate processing apparatus 1 may also be used to process other substrates such as optical disk substrates, magnetic disk substrates, magneto-optical disk substrates, photomask substrates, ceramic substrates, and solar-cell substrates.

The deoxygenation apparatuses 7 and 7a to 7c described above may be used in batch substrate processing apparatuses for processing multiple substrates 9 by immersing the substrates 9 in a processing liquid held in a processing-liquid reservoir. The deoxygenation apparatuses 7 and 7a to 7c are usable in various apparatuses other than substrate processing apparatuses, and may be used independently.

The configurations of the preferred embodiments and variations described above may be appropriately combined as long as there are no mutual inconsistencies.

While the invention has been shown and described in detail, the foregoing description is in all aspects illustrative and not restrictive. It is therefore to be understood that numerous modifications and variations can be devised without departing from the scope of the invention. This application claims priority benefit under 35 U.S.C. Section 119 of Japanese Patent Application No. 2015-71336 filed in the Japan Patent Office on Mar. 31, 2015, the entire disclosure of which is incorporated herein by reference.

### REFERENCE SIGNS LIST

1 Substrate processing apparatus

6 Processing-liquid supply part

7, 7a to 7c Deoxygenation apparatus

70 Target liquid

71 Reservoir

72, 72a to 72c Gas supply part

73 Storage part

74 Arithmetic part

75 Supply control part

722 Gas supply port

723 Supply-port adjusting part

773a Top surface portion (of box part)

774 Slit plate

775, 776 Opening

777, 777b, 777c Supply-port changing part

796 Outer cylinder part

797 Inner cylinder part

798a Small-sized opening

798b Medium-sized opening

798c Large-sized opening

799 Outer opening

1. A deoxygenation apparatus for reducing a concentration of dissolved oxygen in a target liquid, comprising:
a reservoir for holding a target liquid;
a gas supply part for supplying an additive gas that is different from oxygen into said target liquid held in said reservoir;
a storage part for storing correlation information that indicates a relationship between a total supply amount and the concentration of dissolved oxygen in said target liquid, said total supply amount being a total amount of said additive gas supplied from said gas supply part into said target liquid from when supply was started; and
a calculation part for obtaining the concentration of dissolved oxygen in said target liquid on the basis of said total supply amount and said correlation information.

2. The deoxygenation apparatus according to claim 1, further comprising:
a supply control part for controlling a unit supply amount that is an amount of said additive gas supplied from said gas supply part per unit of time,
wherein, when the concentration of dissolved oxygen obtained by said calculation part has dropped to a predetermined target concentration or less, said supply control part reduces said unit supply amount to a concentration-maintaining supply amount that maintains the concentration of dissolved oxygen in said target liquid.

3. The deoxygenation apparatus according to claim 2, wherein
said unit supply amount at the start of supply of said additive gas into said target liquid is a first supply amount, and
said supply control part reduces said unit supply amount to a second supply amount that is less than said first supply amount and greater than said concentration-maintaining supply amount, before the concentration of dissolved oxygen obtained by said calculation part drops to said target concentration.

4. The deoxygenation apparatus according to claim 3, wherein
said gas supply part includes:
a plurality of gas supply ports through which said additive gas is emitted within said reservoir; and
a supply-port adjusting part for increasing the number of said plurality of gas supply ports when said unit supply amount is switched from said first supply amount to said second supply amount.

5. The deoxygenation apparatus according to claim 2, wherein
said gas supply part includes:
a gas supply port through which said additive gas is emitted within said reservoir; and
a supply-port changing part for changing a size of said gas supply port, and said supply-port changing part increases the size of said gas supply port, before the concentration of dissolved oxygen obtained by said calculation part drops to said target concentration.

6. The deoxygenation apparatus according to claim 5, wherein
said gas supply port is an overlapping portion of openings of two plate members that are stacked one on top of the other, and
said supply-port changing part changes an area of said overlapping portion by changing relative positions of said two plate members.

7. A substrate processing apparatus for processing a substrate, comprising:
the deoxygenation apparatus according to claim 1; and
a processing-liquid supply part for supplying a processing liquid to a substrate, said processing liquid including said target liquid having a concentration of dissolved oxygen that has been reduced by said deoxygenation apparatus.

8. A deoxygenation apparatus for reducing the concentration of dissolved oxygen in a target liquid, comprising:
a reservoir for holding a target liquid; and
a gas supply part for supplying an additive gas that is different from oxygen into said target liquid held in said reservoir,
wherein said gas supply part includes:
a gas supply port through which said additive gas is emitted within said reservoir; and
a supply-port changing part for changing a size of said gas supply port.

9. The deoxygenation apparatus according to claim 8, wherein
said gas supply port is an overlapping portion of openings of two plate members that are stacked one on top of the other, and
said supply-port changing part changes an area of said overlapping portion by changing relative positions of said two plate members.

10. A substrate processing apparatus for processing a substrate, comprising:
the deoxygenation apparatus according to claim 8; and
a processing-liquid supply part for supplying a processing liquid to a substrate, said processing liquid including said target liquid having a concentration of dissolved oxygen that has been reduced by said deoxygenation apparatus.
